(19) United States
(12) Patent Application Publication
(10) Pub. No.: US 2013/0161083 A1
(43) Pub. Date: Jun. 27, 2013

(54) PRINTED CIRCUIT BOARDS AND METHODS OF MANUFACTURING PRINTED CIRCUIT BOARDS

(71) Applicants: CHARLES RANDALL MALSTROM, Lebanon, PA (US); Joseph D. Locondro, Jacobus, PA (US); Michael Fredrick Laub, Enola, PA (US); David Bruce Sarraf, Elizabethtown, PA (US)

(72) Inventors: CHARLES RANDALL MALSTROM, Lebanon, PA (US); Joseph D. Locondro, Jacobus, PA (US); Michael Fredrick Laub, Enola, PA (US); David Bruce Sarraf, Elizabethtown, PA (US)

(73) Assignee: Tyco Electronics Corporation, Berwyn, PA (US)

(21) Appl. No.: 13/335,504

(22) Filed: Dec. 22, 2011

(51) Int. Cl. H05K 1/11; H05K 3/12; H05K 1/00

(52) U.S. Cl. 174/266; 174/250; 427/97.3; 205/125

(57) ABSTRACT

A printed circuit board includes a substrate having a first surface, a first conductive circuit deposited on the first surface and a dielectric cover deposited on the first surface and covering at least a portion of the first conductive circuit. The dielectric cover has an edge and the first surface is exposed beyond the edge. A second conductive circuit is deposited on the dielectric cover and the substrate. The second conductive circuit spans the edge such that at least part of the second conductive circuit is deposited on the dielectric cover and at least part of the second conductive circuit is deposited on the first surface.

### BACKGROUND OF THE INVENTION

The subject matter herein relates generally to printed circuit boards and methods of manufacturing printed circuit boards.

Circuit boards are traditionally manufactured using copper clad laminated layers. Conductive copper layers are applied to dielectric layers and then the copper foil is etched away leaving a trace pattern on the layer. The dielectric layers are laminated together, making a multi-layered circuit board. Conventional circuit boards are flat and have each of the layers covering the entire board. Conductive vias extend through the circuit boards to electrically connect traces on different layers. Higher density applications require more layers to route a greater number of circuit traces through the circuit board. The additional layers add thickness to the entire circuit board.

A need remains for a circuit board that can be manufactured on various types of substrates.

### BRIEF DESCRIPTION OF THE INVENTION

In one embodiment, a printed circuit board is provided having a substrate having a first surface, a first conductive circuit deposited on the first surface and a dielectric cover deposited on the first surface and covering at least a portion of the first conductive circuit. The dielectric cover has an edge and the first surface is exposed beyond the edge. A second conductive circuit is deposited on the dielectric cover and the substrate. The second conductive circuit spans the edge such that at least part of the second conductive circuit is deposited on the dielectric cover and at least part of the second conductive circuit is deposited on the first surface.

Optionally, the second conductive circuit may be deposited on and electrically connected to the first conductive circuit. The second conductive circuit may bridge over the first conductive circuit with the dielectric cover positioned between the first and second conductive circuits to electrically isolate the second conductive circuit from the first conductive circuit. Optionally, the second conductive circuit may be non-planer with a first segment of the second conductive circuit being deposited on the first surface and being generally planer and a second segment of the second conductive circuit being deposited on the dielectric cover and transitioning along a curved surface of the dielectric cover.

Optionally, the dielectric cover may be selectively deposited on the first surface in the vicinity of an intersection between the first and second conductive circuits. The dielectric cover may be only slightly wider than the first conductive circuit such that a majority of the substrate is uncovered by the dielectric cover. The dielectric cover may be a bump extending from the first surface over the first conductive surface having a curved transition from the edge toward the center of a dielectric cover.

Optionally, the dielectric cover may have an inner surface and an outer surface. The inner surface may be deposited on and directly engage the first surface and the first conductive circuit. The second conductive surface may be deposited on and directly engage the outer surface of the dielectric cover. The dielectric cover may include a via where at least a portion of the first conductive circuit being exposed in the via. The edge may peripherally surround the via. The second conductive circuit may extend into the via and may engage the first conductive circuit in the via.

Optionally, the first and second conductive circuits may each include a printed conductive trace and a conductive circuit trace. The printed conductive trace may be pad printed and the circuit trace may be electroplated to the printed conductive trace. The dielectric cover may be pad printed on the first surface.

Optionally, the printed circuit board may include a third conductive circuit deposited on the first surface of the substrate. The dielectric cover may cover at least a portion of the third conductive circuit. The first conductive circuit may be discontinuous and have first and second ends located on opposite sides of the third conductive circuit. The second conductive circuit may cross over the third conductive circuit and be electrically connected to the first conductive circuit proximate to the first and second ends. The second conductive circuit may be electrically isolated from the third conductive circuit by the dielectric cover.

In another embodiment, a method of manufacturing a printed circuit board is provided that includes depositing a first conductive circuit on a substrate, depositing a dielectric cover on the substrate and at least part of the conductive circuit, and depositing a second conductive circuit such that at least part of the second conductive circuit is deposited on the dielectric cover and at least part of the second conductive circuit is deposited on the substrate.

Optionally, the first conductive circuit may be deposited by printing a printed conductive trace on the substrate and electroplating the printed conductive trace to define a conductive circuit trace having a higher current carrying capacity than the printed conductive trace. The second conductive circuit may be deposited by printing a printed conductive trace on the substrate across the interface between the substrate and the dielectric cover and on the dielectric cover and electroplating the printed conductive trace to define a conductive circuit trace having a higher current carrying capacity than the second printed conductive trace. The conductive circuit trace may span the interface between the substrate and the dielectric cover. The dielectric cover may be deposited by printing dielectric material onto the substrate in select areas such that portions of the substrate are exposed beyond the dielectric cover.

Optionally, the second conductive circuit may be deposited such that the second conductive circuit is directly electrically connected to the first conductive circuit. The second conductive circuit may be deposited such that the second conductive circuit is electrically isolated from the first conductive circuit by the dielectric cover.

Optionally, the dielectric cover may be deposited on the substrate such that the dielectric cover has a smooth, curved transition from the substrate toward a center of the dielectric cover. The dielectric cover may be deposited on the substrate such that a via is peripherally surrounded by the dielectric cover. The first conductive circuit may be exposed in the via. The second conductive circuit may be deposited such that the second conductive circuit transitions into the via such that the second conductive circuit is electrically connected to the first conductive circuit in the via.

In a further embodiment, a method of manufacturing a printed circuit board is provided including providing a substrate having a base wall and a side wall extending from the base wall. The base wall and the side wall meet at a corner and define a non-planar surface spanning the corner. The method includes printing a conductive circuit on the non-planar surface that spans the corner such that at least part of the conductive circuit is on the base wall and at least part of the conductive circuit is on the side wall. Optionally, the base wall and the side wall may be external walls of a case configured to hold electronic components therein. The base wall and the side wall may have inner surfaces and outer surfaces with the inner surfaces defining a cavity to hold electronic components therein. The method includes printing a conductive circuit on the inner surfaces and/or the outer surfaces of the base wall and the side wall. Optionally, the printing may include pad printing a printed conductive trace and the method may include plating the printed conductive trace to define a conductive circuit trace having a higher current carrying capacity than the printed conductive trace. The method may include depositing a dielectric cover on the base wall to define the side wall.

### BRIEF DESCRIPTION OF THE DRAWINGS

FIG. 1 is a perspective view of a printed circuit board formed in accordance with an exemplary embodiment.

FIG. 2 illustrates an exemplary process of manufacturing a printed circuit board.

FIG. 3 is a perspective view of a printed circuit board formed in accordance with an exemplary embodiment.

FIG. 4 is a cross-sectional view of a portion of the printed circuit board shown in FIG. 3.

FIG. 5 is a bottom perspective view of a printed circuit board formed in accordance with an exemplary embodiment.

FIG. 6 is a top perspective view of the printed circuit board shown in FIG. 5.

### DETAILED DESCRIPTION OF THE INVENTION

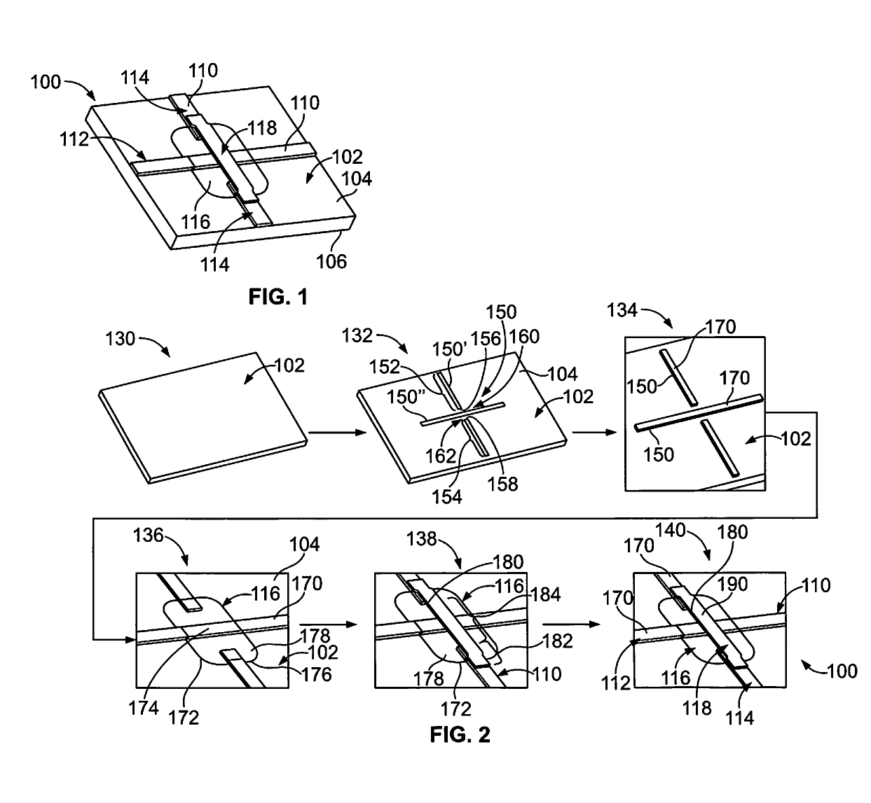

FIG. 1 illustrates a printed circuit board 100 formed in accordance with an exemplary embodiment. The printed circuit board 100 includes a substrate 102 having a first surface 104 and an opposite second surface 106. The substrate 102 defines a base wall of the printed circuit board 100. The substrate 102 may be any kind of substrate. For example, substrate 102 may be a composite material such as FR-4 material. In other embodiments, the substrate 102 may be a plastic material, such as an injection molded plastic, or ceramic material. In other alternative embodiments, the substrate 102 may be a metal substrate, such as an aluminum block, used to define a metal clad circuit board. The substrate 102 may be a planar board and may include one or more layers. In other embodiments, the substrate 102 may be nonplanar and include walls extending from one another in nonplanar orientations. In a particular embodiment, the substrate 102 may be a housing or case of an electronic device, such as a cell phone, pc tablet, computer, gps device, or other electronic device.

In an exemplary embodiment, the printed circuit board 100 includes conductive circuits 110 deposited on one or more surfaces or layers of the substrate 102. Any number of conductive circuits 110 may be provided on the printed circuit board 100. In the illustrated embodiment, the printed circuit board 100 includes a first conductive circuit 112 deposited on the first surface 104, and a second conductive circuit 114 deposited on the first surface 104.

The printed circuit board 100 includes a dielectric cover 116 deposited on the first surface 104 and covering at least a portion of the first conductive circuit 112. The dielectric cover 116 is selectively deposited over a portion of the first conductive circuit 112 proximate to the intersection of the first conductive circuit 112 and the second conductive circuit 114. Optionally, the dielectric cover 116 may cover a portion of the second conductive circuit 114.

A third conductive circuit 118 is deposited on the dielectric cover 116. The third conductive circuit 118 is deposited on and electrically engages the second conductive circuit 114. The third conductive circuit 118 defines part of the circuit path with the second conductive circuit 114. Optionally, the second and third conductive circuits 116, 118 may be printed as a single trace rather than being printed at different times. The third conductive circuit 118 bridges over the first conductive circuit 112 with the dielectric cover 116 positioned between the third conductive circuit 118 and the first conductive circuit 112. The dielectric cover 116 electrically isolates the first conductive circuit 112 from the third conductive circuit 118. The dielectric cover 116 allows the second conductive circuit 114 to cross over the first conductive circuit 112 without having the second conductive circuit 114 electrically connected to the first conductive circuit 112. The printed circuit board 100 uses the third conductive circuit 118 to bridge portions of the second conductive circuit 114 to cross over the first conductive circuit 112 without being electrically connected thereto. The dielectric cover 116 electrically isolates the two circuits 112, 118 from one another.

While the conductive circuits 110 illustrated in FIG. 1 extend generally perpendicular to one another, the conductive circuits 110 may extend in any direction in alternative embodiments. The conductive circuits 110 and the dielectric cover 116 define a stacked circuit configuration. Any number of stacked layers may be utilized by depositing additional dielectric covers 116 and conductive circuits 110. Using a build-up procedure of depositing layers of dielectric covers or bumps and depositing layers of conductive traces allows circuit traces to cross over one another and/or fit in a common space above the substrate to reduce the footprint of the circuits. The build-up procedure allows circuits to be printed and stacked on any type of substrate, such as a case of an electronic device, as opposed to a traditional circuit board having layers of etched copper sheets laminated on dielectric layers. The conductive circuits 110 relatively closer to the substrate 102 are referred to as interior conductive circuits and the conductive circuits 110 relatively further from the substrate 102 within the stack are referred to as exterior conductive circuits. Any length of the interior conductive circuit (e.g. the first conductive circuit 112) may be covered by the dielectric cover 116. The dielectric cover 116 is sized large enough to prevent arching between the conductive circuits 110. The dielectric cover 116 is sized large enough to provide electrical isolation between the conductive circuits 110. Optionally, the third conductive circuit 118 may be covered by another dielectric cover with yet another dielectric circuit extending over the stack of dielectric covers and conductive circuits. A multi layered circuit board is thus provided by stacking conductive circuits 110 and dielectric covers 116.

The conductive circuits 110 may be connected to other electronic components in the vicinity of the intersection of the conductive circuits or remote from the intersection of the conductive circuits. For example, terminals or contacts may be terminated to the conductive circuits 110. The conductive circuits 110 may be electrically connected to other electronic components such as a processor, a battery, or another electronic component mounted to the substrate 102. The conductive circuits 110 may be connected to vias that extend through the printed circuit board 100.

FIG. 2 illustrates an exemplary process of manufacturing a printed circuit board, such as the printed circuit board 100 shown in FIG. 1. FIG. 2 illustrates the printed circuit board 100 at different steps of manufacture, generally identified at 130 through 140. At 130, the substrate 102 is provided. The substrate 102 may have any size or shape depending on the particular application. The substrate 102 may be planar or non-planar.

At 132, a printed conductive trace 150 is deposited on the substrate 102. The printed conductive trace 150 may be a conductive ink applied to the substrate 102. The printed conductive trace 150 may be printed onto the first surface 104 of the substrate 102, such as by pad printing the printed conductive trace 150 on the substrate 102. The printed conductive trace 150 may be deposited by other processes or means in alternative embodiments. For example, the printed conductive trace 150 may be screen printed or laser printed in alternative embodiments.

The printed conductive traces 150 are used to form the conductive circuits 110. The printed conductive traces 150 may have any layout depending on the particular embodiment. Any number of printed conductive traces 150 may be provided. At least some of the printed conductive traces 150 may be connected together to form a common circuit. Other printed conductive traces 150 may be independent from other printed conductive traces 150 to define different conductive circuits. In the illustrated embodiment, one of the printed conductive traces 150′ is discontinuous having a first segment 152 on one side of the other printed conductive trace 150″ and a second segment 154 on the opposite side of the other printed conductive trace 150″. The first and second segments 152, 154 have near ends 156, 158 that are proximate to the other printed conductive trace 150″ but that have spaces or gaps 160, 162 between the segments 152, 154 and the other printed conductive trace 150″.

At 134, conductive circuit traces 170 are deposited on the substrate 102. The conductive circuit traces 170 are deposited on the printed conductive traces 150. The printed conductive traces 150 act as seed layers for depositing the conductive circuit traces 170. In an exemplary embodiment, the conductive circuit traces 170 are deposited by plating the printed conductive traces 150. The conductive circuit traces 170 may be plated by electroplating the printed conductive traces 150. For example, a charge may be applied to the printed conductive traces 150 while the substrate 102 is suspended in a bath of plating material. The plating is attracted to the conductive ink of the printed conductive trace 150 such that the printed circuit board 100 is plated in the areas of the printed conductive trace 150.

The conductive circuit trace 170 may be thicker and/or denser than the printed conductive trace 150. The conductive circuit trace 170 may have a higher current carrying capacity than the printed conductive trace 150. The size of the conductive circuit trace 170 may depend on the type of signals transmitted by the conductive circuit 110. For example, the conductive circuit trace 170 may be thicker for a conductive circuit that conveys power as opposed to a conductive circuit 110 that conveys data. The conductive circuit trace 170 allows more current to be transmitted along the conductive circuits than if only the printed conductive trace 150 were used. In alternative embodiments, rather than plating the printed conductive trace 150 with the conductive circuit trace 170, multiple layers of printed conductive traces 150 may be applied to increase the thickness thereof and thus the current carrying capacity thereof. For example, the multiple printing strokes of printed conductive traces 150 may be applied on the substrate 102. Such embodiments may be used without any post plating.

At 136, the dielectric cover 116 is deposited on the first surface 104 of the substrate 102. The dielectric cover 116 may cover at least a portion of the conductive circuit traces 170. The dielectric cover 116 has an edge 172 where the dielectric cover 116 transitions to the first surface 104. Optionally, the dielectric cover 116 may be shaped like a bump or a mound being thinner proximate to the edge 172 and being thicker proximate to a center 174 of the dielectric cover 116. The dielectric cover 116 may have a curved transition from the edge 172 toward the center 174. Optionally, the dielectric cover 116 may have a plateau at the center 174 wherein the top of the dielectric cover 116 may be generally planer but elevated above the first surface 104.

In an exemplary embodiment, the dielectric cover 116 is deposited on the substrate 102 by pad printing dielectric material onto the substrate 102. The dielectric cover 116 may be deposited by other means or processes in alternative embodiments. For example, the dielectric cover 116 may be injected onto the substrate 102 as a dot or bead. The dielectric cover 116 may be manufactured from any dielectric material. The dielectric cover 116 may be an epoxy.

The dielectric cover 116 has an inner surface 176 and an outer surface 178 opposite the inner surface 176. The inner surface 176 is deposited on and directly engages the first surface 104 and the conductive circuit traces 170. The outer surface 178 is exposed to receive another conductive circuit 110 thereon. The outer surface 178 defines a side wall of the dielectric cover 116, and may be referred to hereinafter as side wall 178. The side wall 178 of the dielectric cover 116 extends outward from the substrate 102, which defines a base wall of the printed circuit board 100. The side wall 178 of the dielectric cover 116 may be curved. Optionally, when the dielectric cover 116 includes a plateau, the plateau may define a top wall of the dielectric cover 116 with the side wall 178 extending between the top wall and the bottom wall defined by the substrate 102.

At 138, a printed conductive trace 180 is deposited on the dielectric cover 116. The printed conductive trace 180 may be similar to the printed conductive trace 150. The printed conductive trace 180 extends across the edge 172 and onto the substrate 102 and or the conductive circuit trace 170 of one of the conductive circuits 110. The printed conductive trace 180 may be applied to the dielectric cover 116 by pad printing using a conductive ink. In an exemplary embodiment, the printed conductive trace 180 is nonplanar where a first segment 182 of the printed conductive trace 180 is deposited on the first surface 104 or the conductive circuit trace 170 and is generally planer and parallel to the plane of the first surface 104. A second segment 184 of the printed conductive trace 180 is deposited on the dielectric cover 116 and transitions along the curved outer surface 178 of the dielectric cover 116. The printing technique for the printed conductive trace 180 allows for printing on nonplanar surfaces. The printing technique for the printed conductive trace 180 allows the conductive ink to be transition along the curved surface of the dielectric cover 116.

At 140, a conductive circuit trace 190 is deposited on the second printed conductive trace 180. The conductive circuit trace 190 may be similar to the conductive circuit trace 170. The conductive circuit trace 190 may be deposited by a plating process, such as an electroplating process. The conductive circuit trace 190 covers the printed conductive trace 180. The conductive circuit trace 190 is electrically connected to and deposited on the conductive circuit trace 170 defining the second conductive circuit 114. The conductive circuit trace 190 defines the third conductive circuit 118. The third conductive circuit 118 is electrically connected to the second conductive circuit 114 and forms part of the same circuit. The conductive circuit trace 190 is electrically isolated from the conductive circuit trace 170 defining the first conductive circuit 112. The third conductive circuit 118 is electrically isolated from the first conductive circuit 112 by the dielectric cover 116.

In other embodiments, as noted above, the printed circuit board may be manufactured without plating or depositing the conductive circuit trace 190. Rather, the printed conductive trace 180 may have enough current carrying capacity. The printed conductive trace 180 may be applied in multiple layers to increase the current carrying capacity without the need for the conductive circuit trace 190.

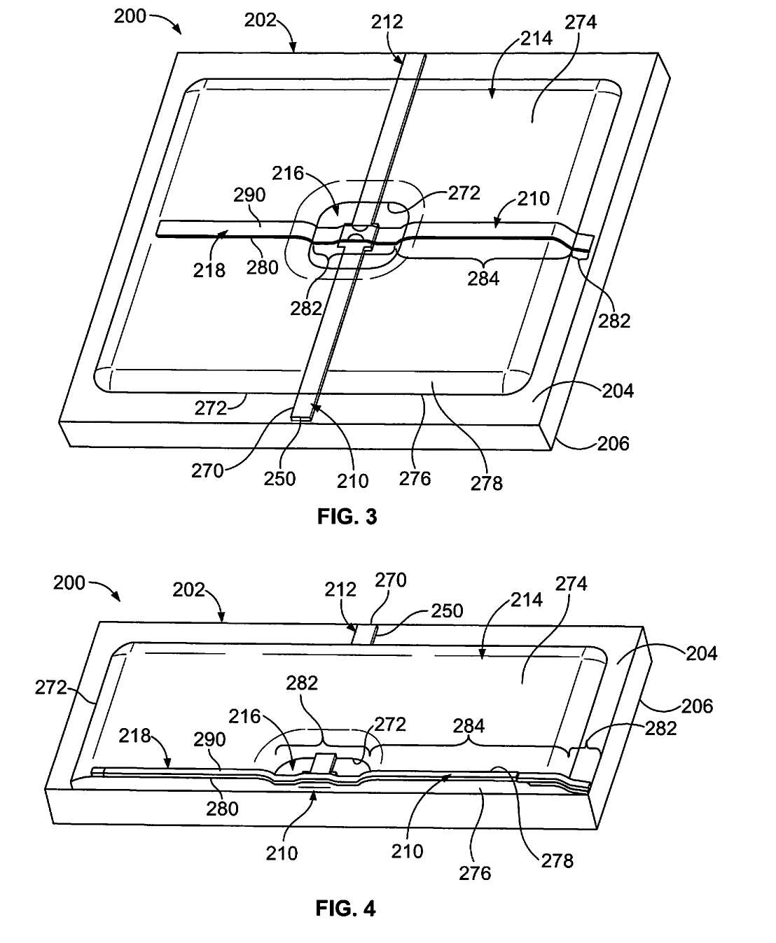

FIG. 3 illustrates a printed circuit board 200 formed in accordance with an exemplary embodiment. FIG. 4 is a cross-sectional view of a portion of the printed circuit board 200. The printed circuit board 200 includes a substrate 202 having a first surface 204 and an opposite second surface 206. The substrate 202 defines a base wall of the printed circuit board 200. The substrate 202 may be similar to the substrate 102 (shown in FIG. 1).

In an exemplary embodiment, the printed circuit board 200 includes conductive circuits 210 deposited on one or more surfaces or layers of the substrate 202. Any number of conductive circuits 210 may be provided on the printed circuit board 200. In the illustrated embodiment, the printed circuit board 200 includes a first conductive circuit 212 deposited on the first surface 204. While only one conductive circuit 210 is illustrated on the first surface 204, any number of conductive circuits 210 may be provided on the first surface 204.

The printed circuit board 200 includes a dielectric cover 214 deposited on the first surface 204 and covering at least a portion of the first conductive circuit 212. The dielectric cover 214 is selectively deposited over a portion of the first conductive circuit 212 and the first surface 204. In an exemplary embodiment, the dielectric cover 214 includes a via 216 or opening therethrough. The via 216 is peripherally surrounded by the dielectric cover 214. In an exemplary embodiment, the first conductive circuit 212 is exposed within the via 216.

A second conductive circuit 218 is deposited on the dielectric cover 214. The second conductive circuit 218 transitions into the via 216 and electrically engages the first conductive circuit 212 within the via 216. The second conductive circuit 218 defines part of a common circuit path with the first conductive circuit 212. The dielectric cover 214 allows the second conductive circuit 218 to cross over other portions of the substrate 102, such as where other conductive circuits 210 are routed, without having the second conductive circuit 218 electrically connected to such other conductive circuits 210. While the second conductive circuit 218 illustrated in FIG. 3 extends generally perpendicular to the first conductive circuit 212, the conductive circuits 212, 218 may extend in any direction in alternative embodiments. The conductive circuits 210 and the dielectric cover 214 define a stacked circuit configuration. The dielectric cover 214 elevates the second conductive circuit 218 at a plane that is elevated above a plane on which the first conductive circuit 214 is located. Any number of stacked layers may be utilized by depositing additional dielectric covers 214 and conductive circuits 210.

The conductive circuits 210 may be connected to other electronic components remote from the intersection of the conductive circuits 210. For example, terminals or contacts may be terminated to the conductive circuits 210. The conductive circuits 210 may be electrically connected to other electronic components such as a processor, a battery, or another electronic component mounted to the substrate 202. The conductive circuits 210 may be connected to vias that extend through the printed circuit board 200.

The printed circuit board 200 may be manufactured in a similar manner as the printed circuit board 100 (shown in FIG. 2). The substrate 202 is provided and may have any size or shape depending on the particular application. The substrate 202 may be planar or non-planar.

A printed conductive trace 250 is deposited on the substrate 202. The printed conductive trace 250 may be a conductive ink applied to the substrate 202. The printed conductive trace 250 may be printed onto the first surface 204 of the substrate 202, such as by pad printing the printed conductive trace 250 on the substrate 202. The printed conductive trace 250 may be deposited by other processes or means in alternative embodiments.

Conductive circuit traces 270 are deposited on the substrate 202. The conductive circuit traces 270 are deposited on the printed conductive traces 250. In an exemplary embodiment, the conductive circuit traces 270 are deposited by plating the printed conductive traces 250. The conductive circuit traces 270 may be plated by electroplating the printed conductive traces 250. The conductive circuit trace 270 may be thicker and/or denser than the printed conductive trace 250. The conductive circuit trace 270 may have a higher current carrying capacity than the printed conductive trace 250.

The dielectric cover 214 is deposited on the first surface 204 of the substrate 202. The dielectric cover 214 may cover at least a portion of the conductive circuit traces 270. The dielectric cover 214 has an edge 272 where the dielectric cover 214 transitions to the first surface 204. One edge 272 surrounds the via 216. Another edge 272 surrounds the sidewall of the dielectric cover 214. The dielectric cover 214 may have a curved transition from the edge 272 toward a top wall 274 of the dielectric cover 214.

In an exemplary embodiment, the dielectric cover 214 is deposited on the substrate 202 by pad printing dielectric material onto the substrate 202. The dielectric cover 214 may be deposited by other means or processes in alternative embodiments. The dielectric cover 214 may be manufactured from any dielectric material. The dielectric cover 214 may be an epoxy.

The dielectric cover 214 has an inner surface 276 and an outer surface 278 opposite the inner surface 276. The inner surface 276 is deposited on and directly engages the first surface 204 and the conductive circuit traces 270. The outer surface 278 is exposed to receive another conductive circuit 210 thereon. The outer surface 278 defines a side wall of the dielectric cover 214, and may be referred to hereinafter as side wall 278. The side wall 278 of the dielectric cover 214 may be curved. One side wall 278 defines the via 216 and extends from the top wall 274 to the edge 272 peripherally surrounding the via 216.

A printed conductive trace 280 is deposited on the dielectric cover 214. The printed conductive trace 280 may be similar to the printed conductive trace 250. The printed conductive trace 280 extends across the edge 272 and into the via 216. The printed conductive trace 280 may extend onto the substrate 202 and the conductive circuit trace 270 defining the first conductive circuit 212. The printed conductive trace 280 may be applied by pad printing using a conductive ink. In an exemplary embodiment, the printed conductive trace 280 is nonplanar where a first segment 282 of the printed conductive trace 280 is deposited on the first surface 204 and the conductive circuit trace 270. A second segment 284 of the printed conductive trace 280 is deposited on the dielectric cover 214 and transitions along the curved outer surface 278 of the dielectric cover 214. The printing technique for the printed conductive trace 280 allows for printing on nonplanar surfaces. The printing technique for the printed conductive trace 280 allows the conductive ink to be transition along the curved surface of the dielectric cover 214.

A conductive circuit trace 290 is deposited on the second printed conductive trace 280. The conductive circuit trace 290 may be similar to the conductive circuit trace 270. The conductive circuit trace 290 may be deposited by a plating process, such as an electroplating process. The conductive circuit trace 290 covers the printed conductive trace 280. The conductive circuit trace 290 is electrically connected to and deposited on the conductive circuit trace 270 defining the first conductive circuit 212. The conductive circuit trace 290 defines the second conductive circuit 218. The second conductive circuit 218 is electrically connected to the first conductive circuit 212 and forms part of the same circuit.

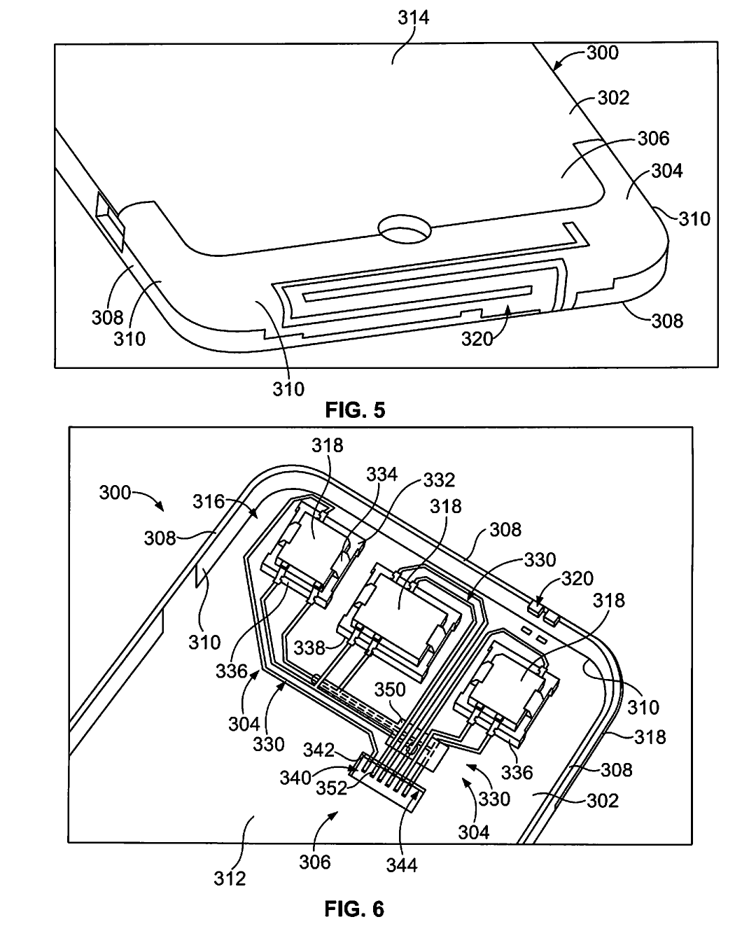

FIGS. 5 and 6 illustrate a printed circuit board 300 formed in accordance with an exemplary embodiment. FIG. 5 is a bottom perspective view of the printed circuit board 300. FIG. 6 is a top perspective view of the printed circuit board 300. The printed circuit board 300 includes a substrate 302 having one or more conductive circuits 304 deposited thereon. The substrate 302 is non-planar and the conductive circuits 304 span across the non-planar surfaces of the substrate 302.

The substrate 302 includes a base wall 306 and a side wall 308 extending from the base wall 306. In the illustrated embodiment, the side wall 308 is oriented generally perpendicular with respect to the base wall 306. The base wall 306 and the side wall 308 meet at a corner 310. The base wall 306 and the side wall 308 span across the corner 310. The base wall 306 and the side wall 308 define a non-planar surface.

In an exemplary embodiment, the base wall 306 and the side wall 308 are external walls of a case or housing configured to hold electronic components therein. For example, the base wall 306 and the side wall 308 may be part of a case of an electronic device, such as a cell phone, a computer, a PC tablet, a GPS device or another type of electronic device. The base wall 306 and the side wall 308 are integrally formed and made from a dielectric material, such as an injection molded polymer, a machined polymer, an extruded polymer, a flexible film, a synthetic composite material, a glass material, a ceramic material a dielectric coated metal material, or any other appropriate dielectric material for the particular application. The base wall 306 and the side wall 308 have inner surfaces 312 and outer surfaces 314. The inner surfaces 312 define a cavity 316 that holds electronic components 318, such as batteries, processors, cameras, displays and the like.

In an exemplary embodiment, the conductive circuits 304 define an antenna 320 on the outer surfaces 314 of the base wall 306 and the side walls 308. Optionally, the antenna 320 may be provided on the inner surfaces 312 in addition to, or in the alternative to, the outer surfaces 314. The antenna 320 extends along the non-planar surfaces of the substrate 302. The antenna 320 may be manufactured in a similar manner as the conductive circuits 110 (shown in FIGS. 1 and 2). The antenna 320 may have a printed conductive trace that is printed, such as by pad printing, on the substrate 302 (e.g. on the base wall 306 and on the side wall 308). Optionally, the printed conductive trace may be printed on both the base wall 306 and the side wall 308 during a single, continuous printing process. For example, the pad may roll across the corner 310 onto both the base wall 306 and the side wall 308 to deposit conductive ink on the surfaces. The printed conductive trace may then be plated, such as by electroplating, with a conductive circuit trace. Optionally, portions of the antenna 320 may be covered by a dielectric cover. Optionally, portions of the dielectric cover may have another conductive circuit deposited thereon. The other conductive circuit may be part of the antenna 320 or may be part of another circuit.

The conductive circuits 304 may define other types of electrical components in other embodiments, such as an inductor, a capacitor, a patch antenna, a dipole antenna, a folded dipole antenna, an F-antenna, a stacked antenna and the like using the printable stacked process of layering printed dielectric and printed conductive layers. The structures rise vertically off the substrate rather than taking up more x-y space on the substrate. For example, for the dipole antenna, printed conductors are stacked with a printed dielectric therebetween and with a feedline connected to the conductors. For example, for the capacitor, any number of conductive layers and dielectric layers may be printed and stacked to get a desired capacitance in a given area of the substrate. For example, for the patch antenna, a ground plane, a dielectric, and a driven element are printed in a stacked arrangement. The driven element is fed at a particular point to match impedance and set polarization, such as at the edge or at the center. For example, for the spiral inductor, a conductor produces a closed perimeter around some area in space (the area enclosed determines the inductance of the structure). Dielectric layers are added by printing and other conductor layers are added by printing, where the conductor layers are connected to other layers, such as through a via through the intervening dielectric layer.

In an exemplary embodiment, the conductive circuits 304 define circuit traces 330 on the inner surface 312 of the base wall 306. Optionally, the circuit traces 330 may be provided on the inner surfaces 312 of the side wall 308 in addition to, or in the alternative to, the base wall 306. The circuit traces 330 may be provided on the outer surfaces 314 in other alternative embodiments. The circuit traces 330 may be used to interconnect various electronic components 318. In an exemplary embodiment, at least some of the circuit traces may be formed as part of a multi-layered or stacked circuit board layout. Stacking the circuit traces reduces the footprint required for routing the circuit traces, which can reduce the overall size of the substrate 302 (and thus the electronic device) or can allow for additional electronic components 318 to be located in a particular area of the substrate that would otherwise be used to route the circuit traces if the circuit traces were not in a stacked configuration. Using the build-up procedure of depositing layers of dielectric covers or bumps and depositing layers of conductive traces allows the circuit traces to be stacked on any type of substrate, such as a case of the electronic device, as opposed to a traditional circuit board having layers of etched copper sheets laminated on dielectric layers.

In an exemplary embodiment, the substrate 302 includes protrusions 332 extending from the base wall 306 interior of the side walls 308. The protrusions 332 are in the cavity 316. The protrusions 332 may be used as mounting locations for the electronic components 318 to hold the electronic components 318, such as using latches 334 or other mounting features. The protrusions 332 have side walls 336. The side walls 336 meet the base wall 306 at corners 338. The corners 338 may have a smooth transition, such as a curved transition, from the base wall 306 to the side wall 336. The circuit traces 330 may extend across the transition from the base wall 306 to the side wall 336. The base walls 306 and the side walls 336 are non-planar. The circuit traces 330 may extend along the non-planar surface defined by the base walls 306 and the side walls 336.

In an exemplary embodiment, the substrate 302 includes pockets or channels 340 extending into the base wall 306. The channels 340 are in the cavity 316. The channels 340 may be used as mounting locations for the electronic components 318 to hold the electronic components 318. The channels 340 have side walls 342. The side walls 342 meet the base wall 306 at corners 344. The corners 344 may have a smooth transition, such as a curved transition, from the base wall 306 to the side wall 342. The circuit traces 330 may extend across the transition from the base wall 306 to the side wall 342. The base walls 306 and the side walls 342 are non-planar. The circuit traces 330 may extend along the non-planar surface defined by the base walls 306 and the side walls 342.

The circuit traces 330 may be manufactured in a similar manner as the conductive circuits 110 (shown in FIGS. 1 and 2). The circuit traces 330 may have a printed conductive trace that is printed, such as by pad printing, on the substrate 302 (e.g. on the base wall 306 and/or on the side walls 336, 342). Optionally, the printed conductive trace may be printed on both the base wall 306 and the side walls 336, 342 during a single, continuous printing process. For example, the pad may roll across the corners 338, 344 onto both the base wall 306 and the side walls 336, 342 to deposit conductive ink on the surfaces. The printed conductive trace may then be plated, such as by electroplating, with a conductive circuit trace. Optionally, portions of the circuit traces 330 may be covered by dielectric covers 350. The dielectric covers 350 may be selectively positioned at discrete locations, such as where a stacked circuit trace configuration is desirable. Portions of the dielectric covers have other circuit traces 330 deposited thereon.

Contacts 352 are terminated to the circuit traces 330 at certain locations, such as at locations that facilitate interfacing with the electronic components 318. The contacts 352 may be soldered to the circuit traces 330. In alternative embodiments, the contacts 352 may be electrically connected to the circuit traces 330 by other means or processes. For example, the contacts 352 may be part of the electronic components 318 and held against the circuit traces 330 by a compression connection.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. § 112, sixth paragraph, unless and until such claim limitations expressly use the phrase “means for” followed by a statement of function void of further structure.

What is claimed is:

1. A printed circuit board comprising:
a substrate having a first surface;
a first conductive circuit deposited on the first surface;
a dielectric cover deposited on the first surface and covering at least a portion of the first conductive circuit, the dielectric cover having an edge, the first surface being exposed beyond the edge; and
a second conductive circuit deposited on the dielectric cover and the substrate, the second conductive circuit spanning the edge such that at least part of the second conductive circuit is deposited on the dielectric cover and at least part of the second conductive circuit is deposited on the first surface.

2. The printed circuit board of claim 1, wherein the second conductive circuit is deposited on and is electrically connected to the first conductive circuit.

3. The printed circuit board of claim 1, wherein the second conductive circuit bridges over the first conductive circuit with the dielectric cover positioned between the first and second conductive circuits to electrically isolate the second conductive circuit from the first conductive circuit.

4. The printed circuit board of claim 1, wherein the dielectric cover is only slightly wider than the first conductive circuit, a majority of the substrate being uncovered by the dielectric cover.

5. The printed circuit board of claim 1, wherein the dielectric cover is a bump extending from the first surface over the first conductive circuit, the bump having a curved transition from the edge toward the center of a dielectric cover.

6. The printed circuit board of claim 1, wherein the dielectric cover has an inner surface and an outer surface, the inner surface being deposited on and directly engaging the first surface and the first conductive circuit, the second conductive circuit being deposited on and directly engaging the outer surface of the dielectric cover.

7. The printed circuit board of claim 1, wherein the dielectric cover includes a via, at least a portion of the first conductive circuit being exposed in the via, the edge peripherally surrounding the via, the second conductive circuit extending into the via and engaging the first conductive circuit in the via.

8. The printed circuit board of claim 1, wherein the first and second conductive circuits each include a printed conductive trace and a conductive circuit trace, the printed conductive trace being pad printed, the conductive circuit trace being electroplated to the printed conductive trace.

9. The printed circuit board of claim 1, wherein the dielectric cover is pad printed on the first surface.

10. The printed circuit board of claim 1, further comprising a third conductive circuit deposited on the first surface of the substrate, the dielectric cover covering at least a portion of the third conductive circuit, the first conductive circuit being discontinuous and having first and second ends located on opposite sides of the third conductive circuit, the second conductive circuit crossing over the third conductive circuit and being electrically connected to the first conductive circuit proximate to the first and second ends, the second conductive circuit being electrically isolated from the third conductive circuit by the dielectric cover.

11. The printed circuit board of claim 1, wherein the second conductive circuit is non-planer with a first segment of the second conductive circuit being deposited on the first surface and being generally planer and a second segment of the second conductive circuit being deposited on the dielectric cover and transitioning along a curved surface of the dielectric cover.

12. A method of manufacturing a printed circuit board, the method comprising:
depositing a first conductive circuit on a substrate;
depositing a dielectric cover on the substrate and at least part of the first conductive circuit; and
depositing a second conductive circuit such that at least part of the second conductive circuit is deposited on the dielectric cover and at least part of the second conductive circuit is deposited on the substrate.

13. The method of claim 12, wherein the depositing a first conductive circuit comprises printing a printed conductive trace on the substrate and electroplating the printed conductive trace to define a conductive circuit trace having a higher current carrying capacity than the printed conductive trace.

14. The method of claim 12, wherein the deposing a second conductive circuit comprises:
printing a printed conductive trace on the substrate across the interface between the substrate and the dielectric cover and on the dielectric cover; and
electroplating the printed conductive trace to define a conductive circuit trace having a higher current carrying capacity than the printed conductive trace, the conductive circuit trace spanning the interface between the substrate and the dielectric cover.

15. The method of claim 12, wherein the depositing a dielectric cover comprises printing dielectric material onto the substrate in select areas such that portions of the substrate are exposed beyond the dielectric cover.

16. The method of claim 12, wherein the depositing a second conductive circuit comprises depositing a second conductive circuit such that the second conductive circuit is directly electrically connected to the first conductive circuit.

17. The method of claim 12, wherein the depositing a second conductive circuit comprises depositing a second conductive circuit such that the second conductive circuit is electrically isolated from the first conductive circuit by the dielectric cover.

18. The method of claim 12, wherein the depositing a dielectric cover comprises depositing a dielectric cover on the substrate such that the dielectric cover has a smooth, curved transition from the substrate toward a center of the dielectric cover.

19. The method of claim 12, wherein the depositing a dielectric cover comprises depositing a dielectric cover on the substrate such that a via is peripherally surrounded by the dielectric cover, the first conductive circuit being exposed in the via, the depositing a second conductive circuit comprises depositing a second conductive circuit on the dielectric cover such that the second conductive circuit transitions into the via, the second conductive circuit being electrically connected to the first conductive circuit in the via.

20. A method of manufacturing a printed circuit board, the method comprising:
providing a substrate having a base wall and a side wall extending from the base wall, the base wall and the side wall meeting at a corner, the base wall and the side wall defining a non-planar surface spanning the corner;
printing a conductive circuit on the non-planar surface, the conductive circuit spanning the corner such that at least part of the conductive circuit is on the base wall and at least part of the conductive circuit is on the side wall.

21. The method of claim 20, wherein the base wall and the side wall are external walls of a case configured to hold electronic components therein.

22. The method of claim 20, wherein the base wall and the side wall have inner surfaces and outer surfaces, the inner surfaces defining a cavity to hold electronic components therein, the method comprising printing a conductive circuit on at least one of the inner surfaces and the outer surfaces of the base wall and the side wall.

23. The method of claim 20, wherein the corner defines an exterior corner, the method comprises printing a conductive circuit on the exterior corner.

24. The method of claim 20, wherein the printing comprises pad printing a printed conductive trace, the method further comprising plating the printed conductive trace to define a conductive circuit trace having a higher current carrying capacity than the printed conductive trace.

25. The method of claim 20, wherein the providing a substrate comprises depositing a dielectric cover on the base wall to define the side wall.
